(19) United States
(12) Patent Application Publication
(10) Pub. No.: US 2017/0133406 A1
(43) Pub. Date: May 11, 2017

(54) METHOD, APPARATUS, AND SYSTEM FOR STACKED CMOS LOGIC CIRCUITS ON FINS

(71) Applicant: GLOBALFOUNDRIES Inc., Grand Cayman (KY)

(72) Inventor: Murat Kerem Akarvardar, Albany, NY (US)

(73) Assignee: GLOBALFOUNDRIES INC., GRAND CAYMAN (KY)

(21) Appl. No.: 14/934,042

(22) Filed: Nov. 5, 2015

(51) Int. Cl. H01L 27/12; H01L 27/088; H01L 29/66; H01L 21/02

(52) U.S. Cl. CPC H01L 27/1211; H01L 21/02236; H01L 21/02598; H01L 27/0886; H01L 29/66795

(57) ABSTRACT

A semiconductor structure, comprising a semiconductor substrate and at least one fin coupled to the semiconductor substrate, wherein the fin comprises at least two active regions and at least one insulator region, wherein all active regions and all insulator regions are stacked and each insulator region is disposed between two active regions. Methods, apparatus, and systems for forming such a semiconductor structure.

### BACKGROUND OF THE INVENTION

### Field of the Invention

Generally, the present disclosure relates to the manufacture of sophisticated semiconductor devices, and, more specifically, to various methods, structures, and systems for preparing semiconductor devices comprising fins with multiple, isolated active regions.

### Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

Fin field-effect transistors (FinFET) devices have been developed to replace conventional planar bulk MOSFETs in advanced CMOS technology due to their improved short-channel effect immunity and Iₒₙ/I_{off} ratio. In an effort to increase device density and reduce wire lengths, various workers have realized that these objectives could be furthered if isolated semiconductor regions could be stacked. A number of attempts have been made to stack isolated semiconductor regions, yet each has one or more shortcomings.

For example, amorphous/poly thin film transistors (TFT) compromise the voltage scaling due to substantially degraded swing.

For another example, formation of a silicon oxide layer by O₂ implantation and annealing (SIMOX) on thick SOI requires a very high temperature anneal (1300° C.) incompatible with silicon/germanium semiconductor materials, and yields undesirably thick insulator (˜100 nm) with undesirably low quality and uniformity.

For a third example, an ultra thin buried oxide (BOX) with SOI has been attempted, but requires an unconventional, expensive substrate; is only feasible on Si-only substrates with a fixed insulator thickness; and the bottommost channel of any stack is on bulk and requires junction isolation between it and the bulk.

For an additional example, epitaxial lateral overgrowth (ELO) from seed windows within an insulator results in defects due to epitaxial growth along the insulator sidewalls. Further, defects arise when epitaxial fronts originating from adjacent seed windows merge

Therefore, at present, there is no practical and low-cost means to achieve stacks of isolated, single crystal, defect-free semiconductor regions.

The present disclosure may address and/or at least reduce one or more of the problems identified above regarding the prior art and/or provide one or more of the desirable features listed above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus, and systems for fabricating a semiconductor structure, comprising a semiconductor substrate and at least one fin coupled to the semiconductor substrate, wherein the fin comprises at least two active regions and at least one insulator region, wherein all active regions and all insulator regions are stacked and each insulator region is disposed between two active regions.

### BRIEF DESCRIPTION OF THE DRAWINGS

The disclosure may be understood by reference to the following description taken in conjunction with the accompanying drawings, in which like reference numerals identify like elements, and in which:

FIG. 1A illustrates a stylized cross-sectional depiction of a semiconductor device after a first stage of processing in accordance with embodiments herein;

FIG. 1B illustrates a stylized cross-sectional depiction of the semiconductor device of FIG. 1A after a second stage of processing in accordance with embodiments herein;

FIG. 1C illustrates a stylized cross-sectional depiction of the semiconductor device of FIGS. 1A-1B after a third stage of processing in accordance with embodiments herein;

FIG. 1D illustrates a stylized cross-sectional depiction of the semiconductor device of FIGS. 1A-1C after a fourth stage of processing in accordance with embodiments herein;

FIG. 1E illustrates a stylized cross-sectional depiction of the semiconductor device of FIGS. 1A-1D after a fifth stage of processing in accordance with embodiments herein;

FIG. 1F illustrates a stylized cross-sectional depiction of the semiconductor device of FIGS. 1A-1E after a sixth stage of processing in accordance with embodiments herein;

FIG. 1G illustrates a stylized cross-sectional depiction of the semiconductor device of FIGS. 1A-1F after a seventh stage of processing in accordance with embodiments herein;

FIG. 2A illustrates a stylized cross-sectional depiction of a semiconductor device after a first stage of processing in accordance with embodiments herein;

FIG. 2B illustrates a stylized cross-sectional depiction of the semiconductor device of FIG. 2A after a second stage of processing in accordance with embodiments herein;

FIG. 2C illustrates a stylized cross-sectional depiction of the semiconductor device of FIGS. 2A-2B after a third stage of processing in accordance with embodiments herein;

FIG. 2D illustrates a stylized cross-sectional depiction of the semiconductor device of FIGS. 2A-2C after a fourth stage of processing in accordance with embodiments herein;

FIG. 2E illustrates a stylized cross-sectional depiction of the semiconductor device of FIGS. 2A-2D after a fifth stage of processing in accordance with embodiments herein;

FIG. 2F illustrates a stylized cross-sectional depiction of the semiconductor device of FIGS. 2A-2E after a sixth stage of processing in accordance with embodiments herein;

FIG. 2G illustrates a stylized cross-sectional depiction of the semiconductor device of FIGS. 2A-2F after a seventh stage of processing in accordance with embodiments herein;

FIG. 3 illustrates a semiconductor device manufacturing system for manufacturing a device in accordance with embodiments herein; and

FIG. 4 illustrates a flowchart of a method in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for a semiconductor structure, comprising a semiconductor substrate and at least one fin coupled to the semiconductor substrate, wherein the fin comprises at least two active regions and at least one insulator region, wherein all active regions and all insulator regions are stacked and each insulator region is disposed between two active regions. Further embodiments herein provide for the formation of such a semiconductor structure.

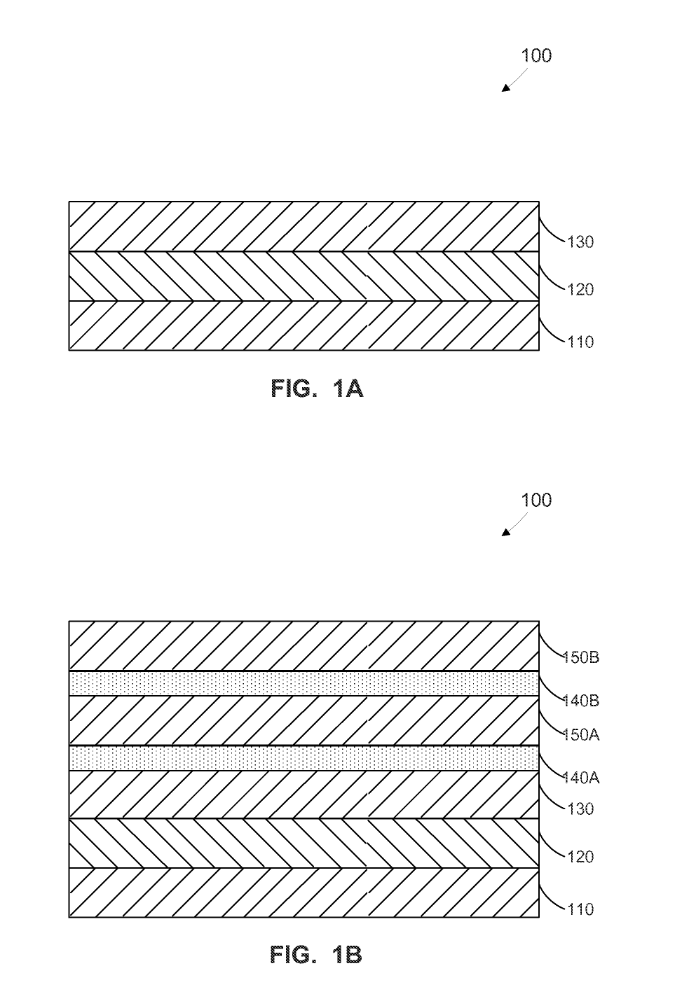

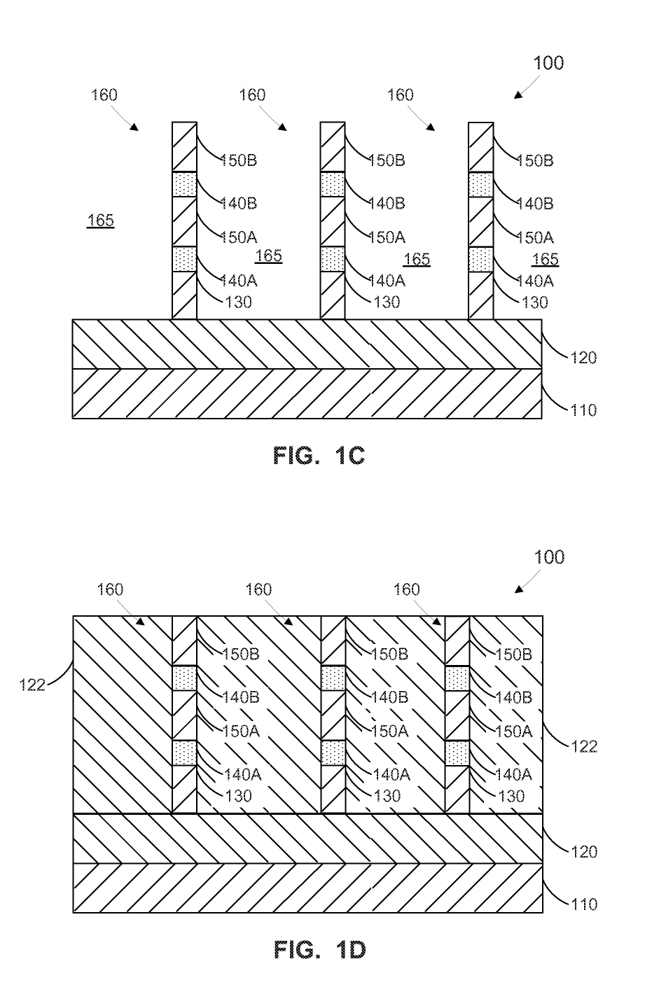

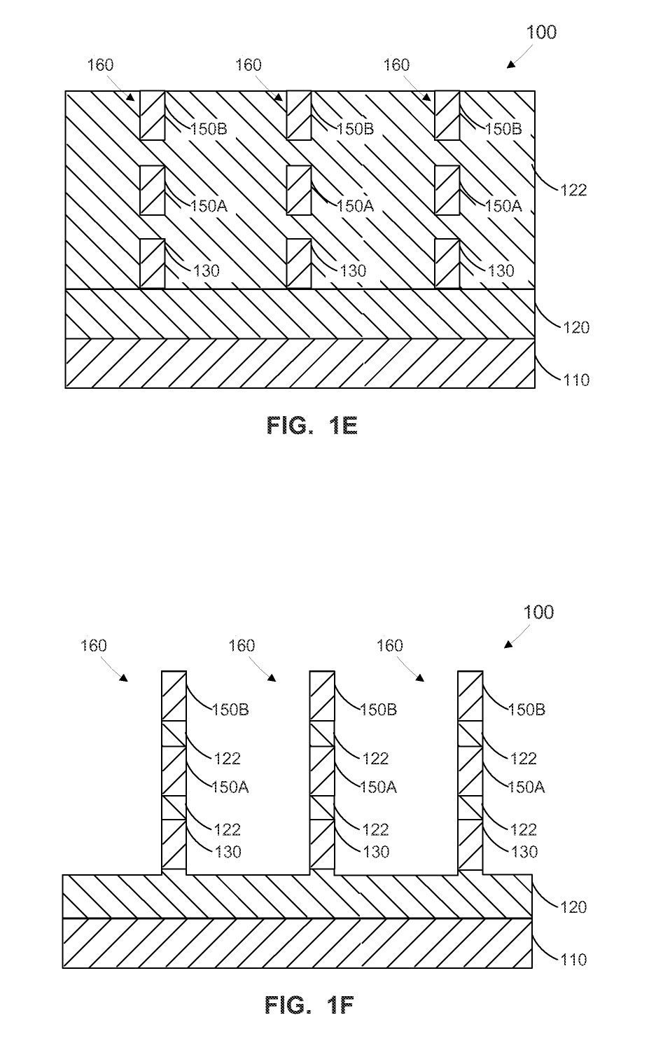

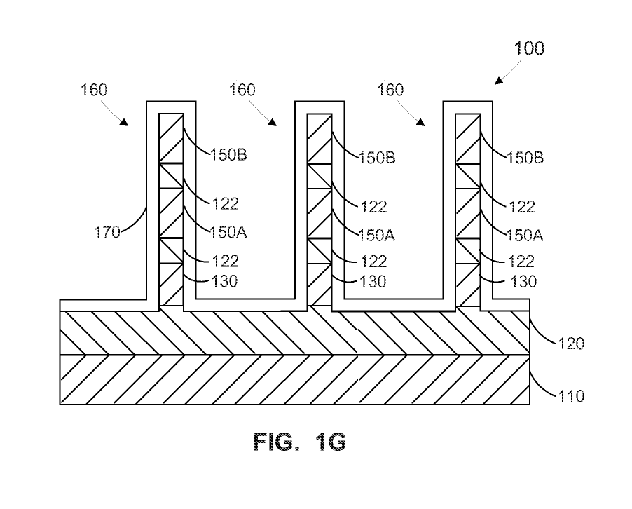

Turning to FIG. 1A, a simplified view of a semiconductor structure, generally denoted by 100, obtained during an intermediate stage of semiconductor fabrication is depicted. At the stage of fabrication depicted in FIG. 1A, the semiconductor structure 100 comprises a semiconductor substrate layer 110. The semiconductor substrate layer 110 may comprise a bulk semiconductor material, for example, bulk silicon; a silicon-on-insulator (SOI) structure; or other material known to the person of ordinary skill in the art for use a semiconductor substrate.

The semiconductor structure 100 depicted in FIG. 1A also comprises an oxide layer 120 and a first semiconductor layer 130. The first semiconductor layer 130 may comprise silicon or other semiconducting material known to the person of ordinary skill in the art. Desirably, the first semiconductor layer 130 comprises a single crystal material. The first semiconductor layer 130 is the uppermost layer of semiconductor structure 100.

Although the semiconductor structure 100 depicted in FIG. 1A shows an SOI structure comprising the three layers 110, 120, and 130, the present disclosure would also be effective with a bulk semiconductor omitting the oxide layer 120.

Turning now to FIG. 1B, a stylized depiction of the semiconductor structure 100 is shown after forming, on the first semiconductor layer 130, a first layer pair A comprising from bottom to top a second semiconductor layer 140A and a third semiconductor layer 150A. The second semiconductor layer 140A and the third semiconductor layer 150A may each comprise silicon, doped silicon, silicon-germanium, doped silicon-germanium, or other semiconducting material known to the person of ordinary skill in the art, provided the second semiconductor layer 140A is more susceptible to oxidation than the first semiconductor layer 130 and the third semiconductor layer 150A.

In one embodiment, the second semiconductor layer 140A comprises silicon germanium having a formula SiₓGe₁₋ₓ, wherein 0≦x≦1. In accordance with embodiments herein, x may be chosen such that 0.3≦x≦1. Desirably, x≈0.5 (i.e., the second semiconductor layer 140A comprises about 50 mol % germanium), which would allow selective oxidation of the layer 140A if layers 130 and 150A are both made of silicon.

The second semiconductor layer 140A and the third semiconductor layer 150A may be formed by any appropriate process. The second semiconductor layer 140A may be formed, for example, by various epitaxial growth processes such as ultra-high vacuum chemical vapor deposition (UHV-CVD), low-pressure CVD (LPCVD), reduced-pressure CVD (RPCVD), rapid thermal CVD (RTCVD) and molecular beam epitaxy (MBE). In one example, the CVD-based epitaxial growth may take place at a temperature of between about 400° C. to about 1100° C., while molecular beam epitaxy may use a lower temperature. In a specific example, wherein the second semiconductor layer 140A comprises SiGe, selective epitaxial growth of SiGe may be performed using halogermanes and silanes as the source gases at temperatures around 600° C.

The second semiconductor layer 140A may have any desired thickness, bearing in mind considerations which will be set forth below. In one embodiment, the second semiconductor layer 140A has a thickness from about 5 nm to about 10 nm.

The third semiconductor layer 150A may be formed, for example, by epitaxial growth over the second semiconductor layer 140A, which growth may stem from processes such as CVD or MBE. The thickness of the third semiconductor layer 150A may be from about 10 nm to about 50 nm. In a specific example, the thickness of the third semiconductor layer 150A may be about 30 nm. In one embodiment, the third semiconductor layer 150A may comprise silicon. A third semiconductor layer 150A comprising silicon may be grown by flowing a reactant gas, such as dichlorosilane (SiH₂Cl₂), trichlorosilane (SiHCl₃), silicontetrachloride (SiCl₄), or silane (SiH₄) together with a carrier gas such as hydrogen gas.

In one embodiment, the third semiconductor layer 150A may comprise the same material as first semiconductor layer 130. Desirably, the third semiconductor layer 150A comprises a single crystal material.

As should be apparent from FIG. 1B, although the immediately preceding paragraphs describe a first layer pair A, the semiconductor structure 100 at this stage of processing may comprise a second layer pair B, comprising a second semiconductor layer 140B and a third semiconductor layer 150B. Layer pair B and its component layers 140B and 150B may be formed using techniques described above. Desirably, the second semiconductor layers 140A and 140B comprise the same material and have the same thickness, and the third semiconductor layers 150A and 150B comprise the same material. Desirably, the third semiconductor layer 150B comprises a single crystal material.

Further, although FIG. 1B depicts two layer pairs A and B, any desired number of layer pairs (not shown) may be formed. For example, three, four, five, six, seven, eight, nine, ten, or even more layer pairs may be formed.

FIG. 1C depicts semiconductor structure 100 after forming fins 160. The semiconductor structure 100 may be etched through the third semiconductor layers 150A, 150B, the second semiconductor layers 140A, 140B, and the first semiconductor layer 130 to create one or more fins 160. The etching process may be performed using any suitable etching process, such as anisotropic dry etching process, for example, reactive-ion-etching (RIE) in sulfur hexafluoride (SF₆). In one example, the fins 160 each include a portion of the third semiconductor layers 150A, 150B, a portion of the second semiconductor layers 140A, 140B and a portion of the first semiconductor layer 130. The fins 160 are separated by openings 165. In one embodiment, the silicon third semiconductor layers 150A, 150B of a fin 160 each have a height of about 30 nm, the silicon germanium second semiconductor layers 140A, 140B each have a height from about 5 nm about 10 nm, and the portion of the first semiconductor layer 130 within the fin has a height of about 30 nm.

Next, the second semiconductor layers 140A, 140B may be selectively oxidized. In one example, selectively oxidizing comprises encapsulating the entire fin with an oxide and subjecting it to a prolonged thermal anneal enables the selective oxidation of the second semiconductor layers 140A, 140B. In this anneal-only case, the oxygen required for the oxidation is supplied by the encapsulating oxide. In another example, selectively oxidizing comprises a prolonged annealing process in the presence of oxygen gas. Oxidizing the second semiconductor layers 140A, 140B of a fin 160 converts the second semiconductor layers 140A, 140B into dielectric layers, effectively electrically isolating from one another the portion of the first semiconductor layer 130 and each of the third semiconductor layers 150A, 150B of the fin 160.

In one embodiment, the fins 160 may be encapsulated in an oxide layer, for example, by a High Aspect Ratio Process (HARP) involving O₃ in the presence of tetraethyl orthosilicate (TEOS) to oxidize the second semiconductor layers 140A, 140B into an oxide. When the anneal process is long enough and the second semiconductor layers 140A, 140B comprise SiGe and have a low thickness, e.g., from about 5 nm to about 10 nm, the second semiconductor layers 140A, 140B transform into SiO₂ layers. In this scenario, Ge atoms are uniformly distributed through the newly formed SiO₂ as well as into the HARP oxide. Some Ge diffusion into the active Si layer above and supporting Si layer below may also take place. Otherwise, if the oxidation or anneal process is not long enough or the second semiconductor layers 140A, 140B are too thick, Ge may remain under the active channel to create a dielectric matrix, for instance, in the form of nanocrystals. Ge nanocrystals under the channel may lead to a leakage path from transistor source to drain. Desirably, selective oxidation proceeds without formation of Ge nanocrystals.

Accordingly, referring to FIG. 1D, the fins 160 are surrounded with an oxide 122 deposited, for example, by a High Density Plasma (HDP) oxide, Flowable Oxide (FOX), or High Aspect Ratio Process (HARP) oxide process or a combination thereof, depending on the width and height of the spaces between fins. In one example, the HARP may include using an O₃/tetraethyl orthosilicate (TEOS) based sub-atmospheric chemical vapor deposition (SACVD) fill process to result in a conformal deposition of silicon oxide. HARP depositions may be advantageous for gap fill depositions of openings with high aspect ratios and may include both a slower deposition rate stage when the slower rate is advantageous for reducing defects, and a higher deposition rate stage when the high rate results in shorter deposition times.

Even if HARP is not used to surround fins 160 with an oxide 122, it is desirable that some technique for depositing oxide 122 is performed. The presence of oxide 122 surrounding fins 160 may provide structural support for the fins 160 during subsequent processing, thereby better maintaining the structural integrity of fins 160 relative to processes in which oxide 122 is not deposited to surround fins 160.

As depicted in FIG. 1E, after the HARP deposition, the semiconductor structure 100 is subjected to a selective oxidation process in the presence of the oxide 122 selectively oxidizing the second semiconductor layers 140A, 140B. Although Fig. lE shows oxide 122 in the locations formerly occupied by second semiconductor layers 140A, 140B, the selectively oxidized regions may, but need not, comprise a different oxide than that deposited to form the structure of FIG. 1D.

The selective oxidation process may be performed, for example, by subjecting the HARP oxide to a rapid thermal oxidation (RTO) procedure or by subjecting to a steam annealing procedure. It may be noted that performing the selective oxidation, for example, by annealing the second semiconductor layers 140A, 140B in the presence of a HARP oxide 122 encapsulating the fins 160, electrically isolates the active layer by converting the second semiconductor layers 140A, 140B into dielectric material, while also providing mechanical/physical stability to the fin structure and preventing the fin structure from tilting due to stress caused by the oxidation of the second semiconductor layers 140A, 140B. There are many different scenarios and time/temperature combinations that would achieve the oxidation. In one example, the rapid thermal oxidation may be performed at about 900° C. for about 15 seconds. In another example, steam annealing may be performed in the presence of water vapor at about 500° C. for about 6 hours.

FIG. 1F depicts semiconductor structure 100 after a subsequent processing event. Specifically, the oxide 122 surrounding but not within fins 160 is removed. Removal of the oxide 122 may be effected by any appropriate technique. In one embodiment, the oxide 122 is removed by performing an anisotropic oxide recess. An anisotropic oxide recess may etch oxide layer 120 below the bottom of first semiconductor layer 130 in fins 160. Regardless of how the oxide 122 surrounding but not within fins 160 is removed, the semiconductor structure 100 depicted in FIG. 1F may be used to fabricate any of a number of semiconductor devices.

Desirably, each of first semiconductor layer 130 and the third semiconductor layers 150A, 150B each comprises a single crystal material. Single crystal materials may allow fins 160 to be components of stacked FinFET circuits having higher performance and fewer shortcomings than the attempted stacked isolated semiconductor regions of the prior art. Alternatively or in addition, single crystal materials may allow fins 160 to be components of stacked FinFET circuits with substantially reduced area or substantially greater device density than conventional FinFETs.

FIG. 1G depicts semiconductor structure 100 after a subsequent, optional processing event. Specifically, gate structure 170 is disposed on the fins 160. The semiconductor structure 100 depicted in FIG. 1G may be used to fabricate any of a number of semiconductor devices.

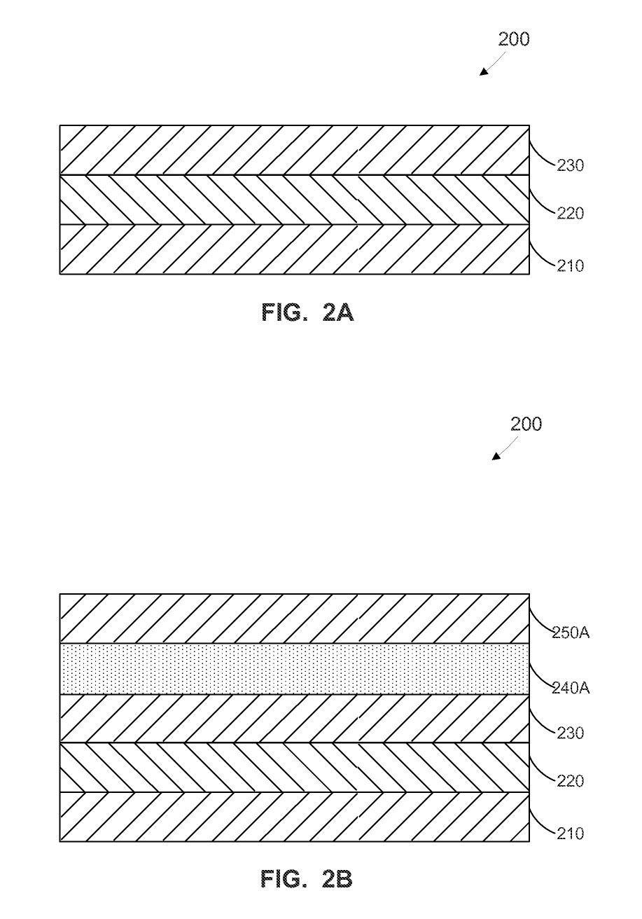

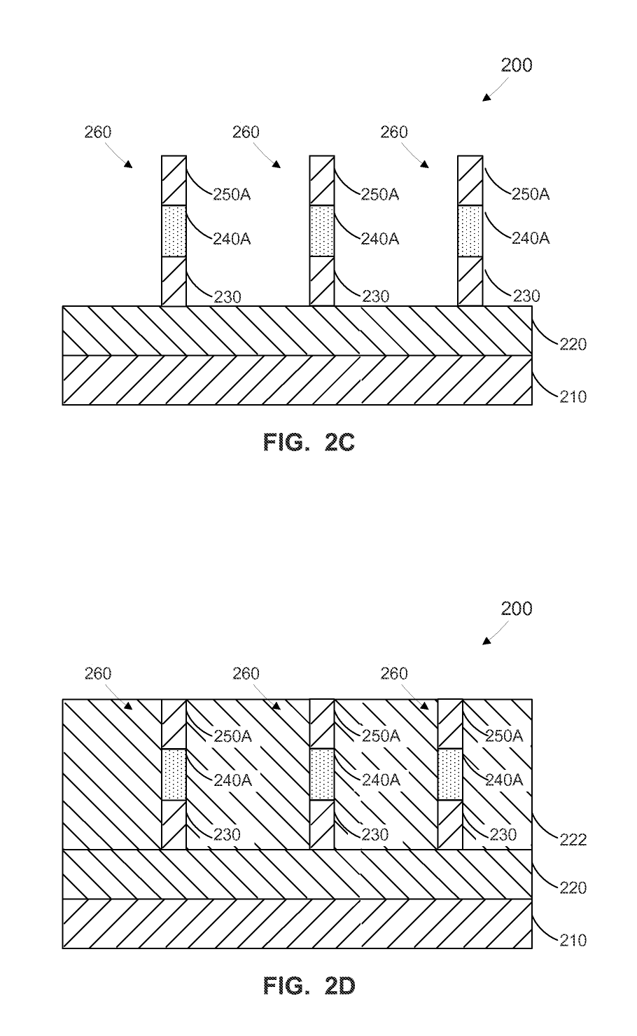

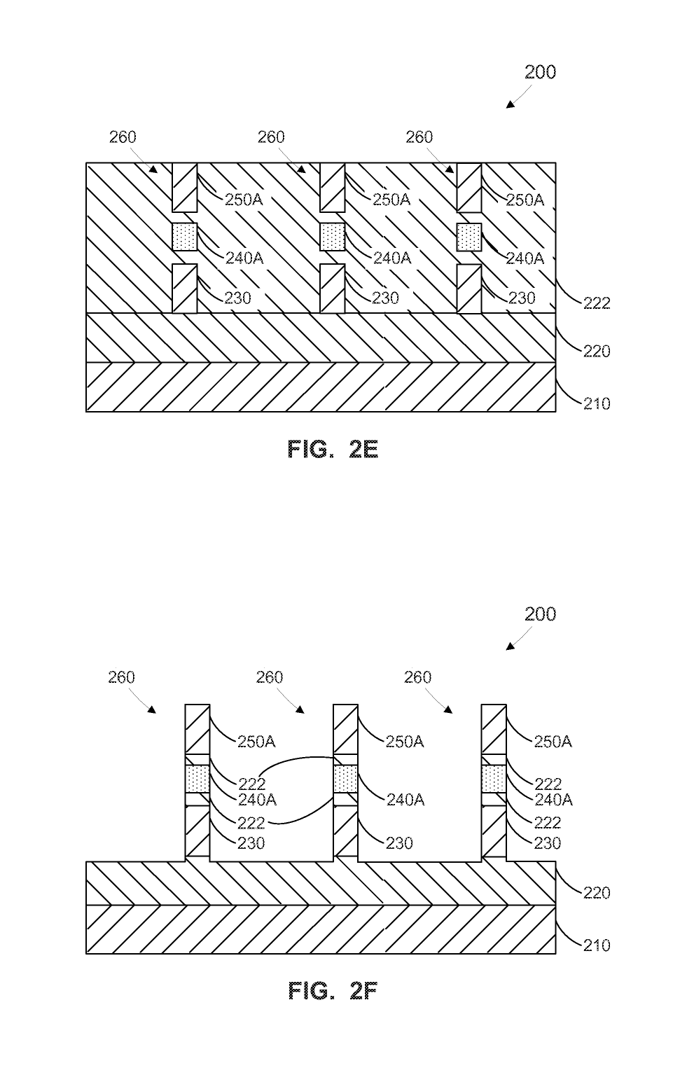

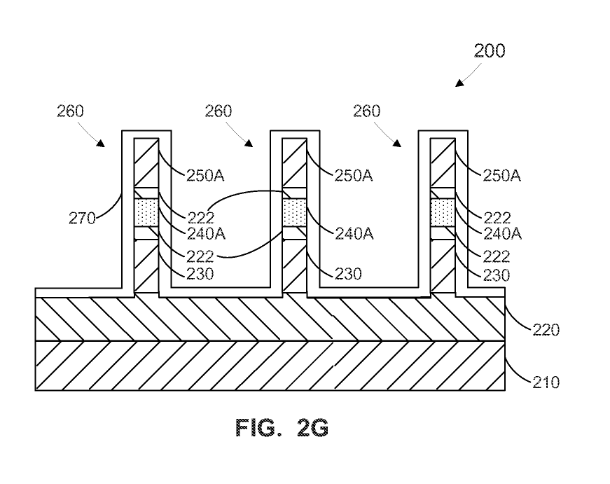

Turning now to FIG. 2A, a second embodiment of a semiconductor structure, generally indicated as 200, is depicted. Throughout FIGS. 2A-2G, numerous depicted elements may be comparable to elements set forth in FIGS. 1A-1G and the accompanying discussion of those figures, above. Such comparable elements will be indicated in FIGS. 2A-2G with reference numerals having the same final two digits (and letter suffix, if any) as the corresponding reference numeral in FIGS. 1A-1G. The comparable elements in FIGS. 2A-2G will have a first digit of “2,” compared to a first digit of “1” in FIGS. 1A-1G. For the sake of brevity, such comparable elements will not be described in detail below. The description of FIGS. 2A-2G will focus on differences relative to FIGS. 1A-1G.

FIG. 2B shows a first layer pair A, comprising second semiconductor layer 240A and third semiconductor layer 250A. The second semiconductor layer 240A may have any desired thickness, bearing in mind considerations which will be set forth below. In one embodiment, the second semiconductor layer 240A has a thickness greater than about 10 nm, for example, a thickness from about 20 nm to about 50 nm. The second semiconductor layer 240A may comprise silicon germanium having a formula SiₓGe₁₋ₓ, wherein x≦1. Desirably, x may be chosen such that 0≦x≦0.3 (i.e., second semiconductor layer 240A may comprise from about 70 mol % to about 100 mol % germanium). Alternatively or in addition, desirably, the second semiconductor layer 240A comprises a single crystal material.

Although FIG. 2B depicts only one layer pair A, the semiconductor structure 200 at this stage of processing may comprise at least one second layer pair. Any desired number of layer pairs (not shown) may be formed. For example, two, three, four, five, six, seven, eight, nine, ten, or even more layer pairs may be formed.

The semiconductor structure 200 may then undergo fin formation (resulting in the semiconductor structure 200 depicted in FIG. 2C comprising fins 260) and selective oxidation of the interfaces between the second semiconductor layer 240A and the first and third semiconductor layers 230 and 250A. Selective oxidation of the interfaces may comprise depositing an oxide 222, resulting in the semiconductor structure 200 depicted in FIG. 2D.

FIG. 2E depicts the semiconductor structure 200 after an annealing or comparable event by which a portion of second semiconductor layer 240A is oxidized. When second semiconductor layer 240A is chosen to be relatively thick, e.g., from about 20 nm to about 50 nm, in contrast to the thickness of about 5 nm to about 10 nm of the second semiconductor layer 140A of the embodiment depicted in FIGS. 1B-1D; and/or the second semiconductor layer 240A comprises more germanium, e.g., from about 70 mol % to about 100 mol % germanium, in contrast to the first semiconductor layer 140A, which may comprise about 50 mol % germanium, then oxidation of the second semiconductor layer 240A may begin at the interfaces between second semiconductor layer 240A and first semiconductor layer 230 or third semiconductor layer 250A. As a result, a portion of the second semiconductor layer 240A may remain within fin 260, with oxide regions disposed at the interfaces between the second semiconductor layer 240A and first semiconductor layer 230 or third semiconductor layer 250A.

Thus, as shown in FIG. 2F, oxidizing only the portions of the second semiconductor layer 240A of a fin 260 at the interface between the second semiconductor layer 240A and the first semiconductor layer 230 or the second semiconductor layer 250A creates dielectric regions 222, effectively electrically isolating from one another the portion of the first semiconductor layer 230, the second semiconductor layer 240A, and the third semiconductor layers 250A of the fin 260.

Desirably, each of first semiconductor layer 230 and the third semiconductor layers 250A, 250B each comprises a single crystal material. Single crystal materials may allow fins 260 to be components of stacked FinFET circuits having higher performance and fewer shortcomings than the attempted stacked isolated semiconductor regions of the prior art. Alternatively or in addition, single crystal materials may allow fins 260 to be components of stacked FinFET circuits with substantially reduced area or substantially greater device density than conventional FinFETs.

Thereafter, the semiconductor structure 200 depicted in FIG. 2F may be further processed to manufacture any of a variety of semiconductor devices. For example, a gate structure 270 may be deposited over fins 260, resulting in the semiconductor structure 200 depicted in FIG. 2G.

Regardless of how a semiconductor structure 100, 200 is made, a method of the present invention may produce a semiconductor structure, comprising a semiconductor substrate; and at least one fin coupled to the semiconductor substrate, wherein the fin comprises at least two active regions and at least one insulator region, wherein all active regions and all insulator regions are stacked and each insulator region is disposed between two active regions. For example, the fin may comprise three active regions and two insulator regions.

In one embodiment, the semiconductor substrate may comprise bulk silicon or silicon-on-insulator, and the active regions may comprise silicon, silicon-germanium, or both.

Alternatively or in addition, the semiconductor structure may further comprise a gate structure on a top and sidewalls of the fin.

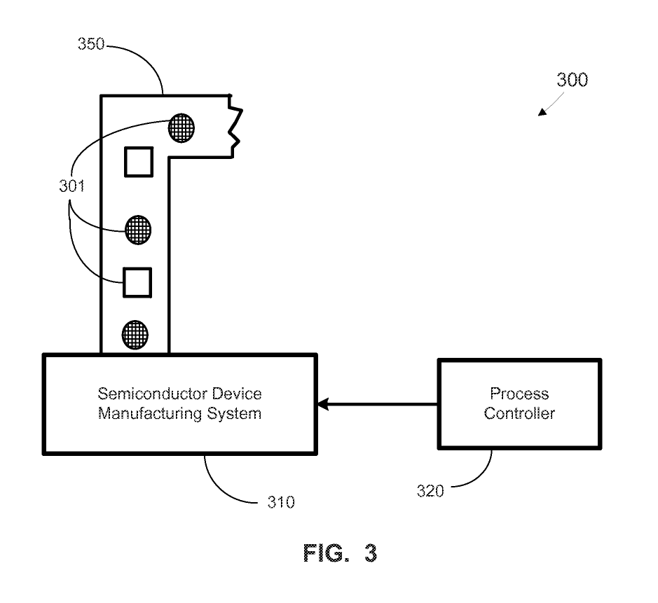

Turning now to FIG. 3, a stylized depiction of a system for fabricating a semiconductor device 100, in accordance with embodiments herein, is illustrated. The system 300 of FIG. 3 may comprise a semiconductor device manufacturing system 310 and a process controller 320. The semiconductor device manufacturing system 310 may manufacture semiconductor devices based upon one or more instruction sets provided by the process controller 320. In one embodiment, a first instruction set may comprise instructions to provide a semiconductor substrate comprising a first semiconductor layer as an uppermost layer; form, on the first semiconductor layer, a first layer pair comprising from bottom to top a second semiconductor layer and a third semiconductor layer, wherein the second semiconductor layer is more susceptible to oxidation than the first semiconductor layer and the third semiconductor layer; form a fin comprising the first semiconductor layer and the first layer pair; and selectively oxidize the second semiconductor layer. In one embodiment, a second instruction set may comprise instructions to provide a semiconductor substrate comprising a first semiconductor layer on the first oxide; form, on the first semiconductor layer, a first layer pair comprising from bottom to top a second semiconductor layer and a third semiconductor layer, wherein the second semiconductor layer is more susceptible to interface oxidation than the first semiconductor layer and the third semiconductor layer; form a fin comprising the first semiconductor layer and the first layer pair; and selectively oxidize a lower portion of the second semiconductor layer at an interface between the second semiconductor layer and the first semiconductor layer and an upper portion of the second semiconductor layer at an interface between the second semiconductor layer and the third semiconductor layer.

The semiconductor device manufacturing system 310 may comprise various processing stations, such as etch process stations, photolithography process stations, CMP process stations, etc. One or more of the processing steps performed by the semiconductor device manufacturing system 310 may be controlled by the process controller 320. The process controller 320 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 310 may produce semiconductor devices 301 (e.g., integrated circuits) on a medium, such as silicon wafers. The semiconductor device manufacturing system 310 may provide processed semiconductor devices 301 on a transport mechanism 350, such as a conveyor system. In some embodiments, the conveyor system may be sophisticated clean room transport systems that are capable of transporting semiconductor wafers. In one embodiment, the semiconductor device manufacturing system 310 may comprise a plurality of processing steps, e.g., the 1^{st} process step, the 2^{nd} process step, etc.

In some embodiments, the items labeled “301” may represent individual wafers, and in other embodiments, the items 301 may represent a group of semiconductor wafers, e.g., a “lot” of semiconductor wafers. The semiconductor device 301 may comprise one or more of a transistor, a capacitor, a resistor, a memory cell, a processor, and/or the like.

The system 300 may be capable of manufacturing various products involving various technologies. For example, the system 300 may produce devices of CMOS technology, Flash technology, BiCMOS technology, power devices, memory devices (e.g., DRAM devices), NAND memory devices, and/or various other semiconductor technologies.

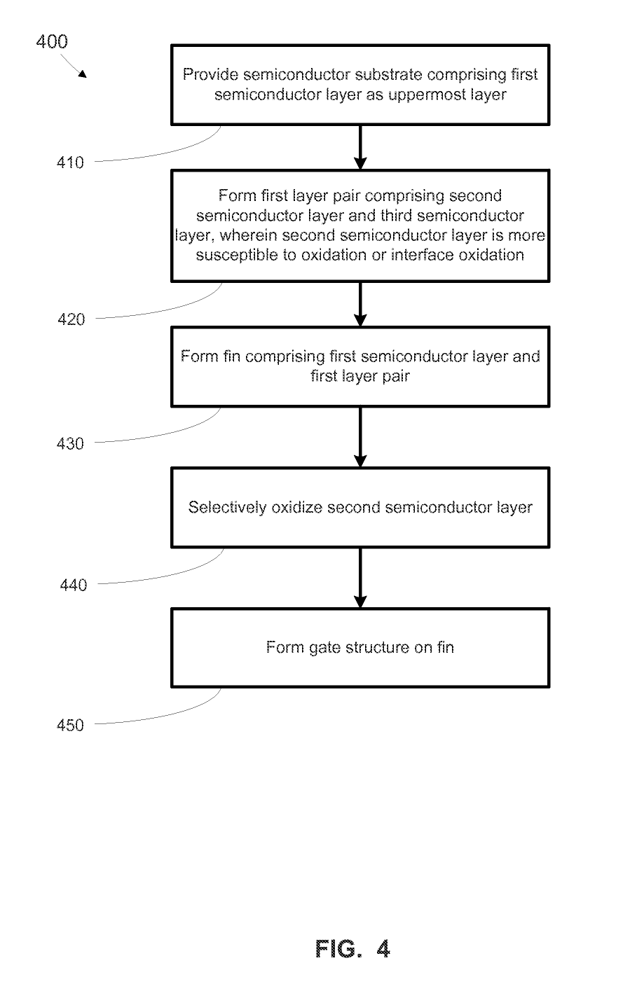

Turning to FIG. 4, a flowchart of a method 400 in accordance with embodiments herein is depicted. The method 400 comprises providing (at 410) a semiconductor substrate comprising a first semiconductor layer as an uppermost layer. The semiconductor substrate may further comprise one or more additional layers. In one embodiment, the semiconductor substrate further comprises an oxide layer below the first semiconductor layer, and a substrate layer below the oxide layer, e.g., SOI is used instead of bulk.

The method 400 also comprises forming (at 420), on the first semiconductor layer, a first layer pair comprising from bottom to top a second semiconductor layer and a third semiconductor layer. In one embodiment, the second semiconductor layer is more susceptible to oxidation than the first semiconductor layer and the third semiconductor layer. In another embodiment, the second semiconductor layer is more susceptible to interface oxidation than the first semiconductor layer and the third semiconductor layer.

In one embodiment, the second semiconductor layer comprises silicon-germanium. A silicon-germanium second semiconductor layer may have a thickness from about 5 nm to about 10 nm. At least one second layer pair may also be formed.

The method 400 also comprises forming (at 430) a fin comprising the first semiconductor layer and the first layer pair. The fin may be formed by a process comprising a reactive ion etch (RIE).

The method 400 also comprises selectively oxidizing (at 440) either the second semiconductor layer, or a lower portion of the second semiconductor layer at an interface between the second semiconductor layer and the first semiconductor layer and an upper portion of the second semiconductor layer at an interface between the second semiconductor layer and the third semiconductor layer. In one embodiment, selectively oxidizing comprises conformally depositing an oxide so as to encapsulate the fin, which may provide a mechanical anchor to fin structures; and annealing the fin and conformal oxide to oxidize the second semiconductor layer in the fin.

In one embodiment, the method 400 may further comprise forming (at 450) a gate structure on a top and sidewalls of the fin.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. A method, comprising:
providing a semiconductor substrate comprising a first semiconductor layer as an uppermost layer;
forming, on the first semiconductor layer, a first layer pair comprising from bottom to top a second semiconductor layer and a third semiconductor layer, wherein the second semiconductor layer is more susceptible to oxidation than the first semiconductor layer and the third semiconductor layer;
forming a fin comprising the first semiconductor layer and the first layer pair; and
selectively oxidizing the second semiconductor layer.

2. The method of claim 1, further comprising forming, on the first layer pair, at least one second layer pair comprising from bottom to top the second semiconductor layer and the third semiconductor layer, wherein the fin comprises the first semiconductor layer, the first layer pair, and the at least one second layer pair; and selectively oxidizing comprises selectively oxidizing the second semiconductor layer in both the first layer pair and each of the at least one second layer pairs.

3. The method of claim 1, wherein the semiconductor substrate further comprises an oxide layer below the first semiconductor layer, and a substrate layer below the oxide layer.

4. The method of claim 1, wherein the second semiconductor layer comprises silicon-germanium.

5. The method of claim 4, wherein the second semiconductor layer has a thickness from about 5 nm to about 10 nm.

6. The method of claim 1, wherein the first semiconductor layer and the third semiconductor layer each comprises a single crystal material.

7. The method of claim 1, wherein selectively oxidizing comprises conformally depositing an oxide so as to encapsulate the fin; and annealing the fin and conformal oxide to oxidize the second semiconductor layer in the fin.

8. The method of claim 1, further comprising forming a gate structure on a top and sidewalls of the fin.

9. A method, comprising:
providing a semiconductor substrate comprising a first semiconductor layer on the first oxide;
forming, on the first semiconductor layer, a first layer pair comprising from bottom to top a second semiconductor layer and a third semiconductor layer, wherein the second semiconductor layer is more susceptible to interface oxidation than the first semiconductor layer and the third semiconductor layer;
forming a fin comprising the first semiconductor layer and the first layer pair; and
selectively oxidizing a lower portion of the second semiconductor layer at an interface between the second semiconductor layer and the first semiconductor layer and an upper portion of the second semiconductor layer at an interface between the second semiconductor layer and the third semiconductor layer.

10. The method of claim 9, further comprising forming, on the first layer pair, at least one second layer pair comprising from bottom to top the second semiconductor layer and the third semiconductor layer, wherein the fin comprises the first semiconductor layer, the first layer pair, and the at least one second layer pair; and selectively oxidizing comprises selectively oxidizing the lower portion and the upper portion of each second semiconductor layer in both the first layer pair and each of the at least one second layer pairs.

11. The method of claim 9, wherein the second semiconductor layer comprises silicon-germanium.

12. The method of claim 11, wherein the second semiconductor layer has at least one of (a) a thickness from about 20 nm to about 50 nm or (b) a germanium content greater than about 70 mol %.

13. The method of claim 9, wherein the first semiconductor layer, the second semiconductor layer, and the third semiconductor layer each comprises a single crystal material.

14. The method of claim 9, wherein selectively oxidizing comprises conformally depositing an oxide so as to encapsulate the fin; and annealing the fin and conformal oxide to oxidize the upper and lower portions of the second semiconductor layer in the fin.

15. The method of claim 9, further comprising forming a gate structure on a top and sidewalls of the fin.

16. A semiconductor structure, comprising:
a semiconductor substrate; and
at least one fin coupled to the semiconductor substrate, wherein the fin comprises at least two active regions and at least one insulator region, wherein all active regions and all insulator regions are stacked and each insulator region is disposed between two active regions.

17. The semiconductor structure of claim 16, wherein the fin comprises three active regions and two insulator regions.

18. The semiconductor structure of claim 16, wherein the semiconductor substrate comprises bulk silicon or silicon-on-insulator, and the active regions comprise silicon, silicon-germanium, or both.

19. The semiconductor structure of claim 16, further comprising a gate structure on a top and sidewalls of the fin.

20. The semiconductor structure of claim 16, wherein each active region comprises a single crystal material.
